(19) United States
(12) Patent Application Publication
(10) Pub. No.: US 2026/0223515 A1
(43) Pub. Date: Jul. 30, 2026

(54) Display System with Reduced Crosstalk Contamination

(71) Applicant: 3M INNOVATIVE PROPERTIES COMPANY, St. Paul, MN (US)

(72) Inventors: Jihoon Yu, Gwangmyeong-si (KR); Seohern Lee, Gyeonggi-do (KR)

(21) Appl. No.: 19/148,789

(22) PCT Filed: Jan. 10, 2024
(86) PCT No.: PCT/IB2024/050255

§ 371 Date: Jul. 17, 2025

Related U.S. Application Data
(60) Provisional application No. 63/440,147, filed on Jan. 20, 2023.

(51) Int. Cl. H10H 29/855; H10H 29/851

(52) U.S. Cl. CPC H10H 29/855; H10H 29/8514

(57) ABSTRACT

A display includes a light emission film, a light-converting film, and an optical film disposed therebetween. The light emission film includes first pixels arranged at a spacing d1 and configured to emit light having a same emitted spectrum with an emission peak at an emitted peak wavelength. The light-converting film includes second pixels arranged at a spacing d2 and aligned with the first pixels. The light emission and light-converting films are spaced apart from each other by a distance D. The second pixels include light-converting green and red pixels which receive and convert emitted light from the first pixels to respective green and red light. For the emitted peak wavelength, the optical film has a transmittance T1 for an angle a1 less than 10 degrees and a transmittance T2 for a different angle a2, where tan(a2)=(d1+d2)/(2D) and T2/T1≤0.8.

### SUMMARY

In some aspects of the present description, a display is provided, the display including a light emission film, a light-converting film, and an optical film disposed between, and substantially co-extensive in length and width with, the light emission and light-converting films. The light emission film includes a plurality of first pixels arranged at an average spacing d1 from each other and configured to emit light having substantially a same emitted spectrum comprising an emission peak at an emitted peak wavelength. The light-converting film includes a plurality of second pixels arranged at an average spacing d2 from each other and disposed on, and aligned in one-to-one correspondence with, the first pixels. The light emission and light-converting films are spaced apart from each other by an average distance D along a thickness direction of the display. The plurality of second pixels include at least pluralities of light-converting green pixels and light-converting red pixels having respective green and red converting spectra and configured to receive and convert at least portions of the emitted light from their corresponding first pixels to respective green and red light within the respective green and red converting spectra. The optical film includes a plurality of microlayers numbering at least 10 in total, and each of the microlayers has an average thickness of less than about 500 nm. For the emitted peak wavelength and at least one polarization state, the optical film has an optical transmittance T1 for a first incident angle a1 of less than about 10 degrees and an optical transmittance T2 for a different, second incident angle a2, such that tan(a2)=(d1+d2)/(2D), and T2/T1 is less than or equal to about 0.8.

In some aspects of the present description, a display is provided, the display including a light emission film, a light-converting film, and an optical film disposed between, and substantially co-extensive in length and width with, the light emission and light-converting films. The light emission film includes a plurality of blue pixels configured to emit blue light having an emitted spectrum having an emission peak and a corresponding blue full width at half maximum FWHM(b). The light-converting film includes pluralities of light-converting green pixels and light-converting red pixels having respective green and red converting spectra with respective green and red peaks and a corresponding respective green full width at half maximum FWHM(g) and a red full width at half maximum FWHM(r). For each of mutually orthogonal first and second polarization states, and for wavelength ranges across FWHM(b), FWHM(g), and FWHM(r), the optical film has respective average optical transmittances S1b, S1g, and S1r for a first incident angle of less than about 10 degrees and respective average optical transmittances S2b, S2g, and S2r for a different, second incident angle of greater than about 20 degrees, such that each of S1g, S1r, S2g, and S2r is less than about 15%, S1b is greater than about 60%, and S2b is less than about 60%.

### BRIEF DESCRIPTION OF THE DRAWINGS

FIG. 1 is a side view of a display with reduced crosstalk contamination, in accordance with an embodiment of the present description;

FIG. 2 is another side view of a display with reduced crosstalk contamination, in accordance with an embodiment of the present description;

FIG. 3 is a graph plotting the optical transmittances for a display with reduced crosstalk contamination, in accordance with an embodiment of the present description;

FIGS. 4A and 4B present optical transmittance data for a display with reduced crosstalk contamination, in accordance with an embodiment of the present description; and

FIG. 5 is a cross-sectional, side view of a multilayer optical film including a plurality of alternating microlayers, in accordance with an embodiment of the present description.

### DETAILED DESCRIPTION

In the following description, reference is made to the accompanying drawings that form a part hereof and in which various embodiments are shown by way of illustration. The drawings are not necessarily to scale. It is to be understood that other embodiments are contemplated and may be made without departing from the scope or spirit of the present description. The following detailed description, therefore, is not to be taken in a limiting sense.

Today, self-emissive micro-LED displays often rely on a monolithic micro-LED array (e.g., all LEDs emit blue or ultraviolet wavelengths) with a color conversion layer to convert the display to a full RGB (red-green-blue) display. A color conversion layer (such as a conversion layer including pixels with quantum dots to convert the blue or ultraviolet light to appropriate red, green, and blue spectra pixels) can be manufactured more simply and for a lower cost (higher yield) that direct RGB-type micro-LED displays. However, a problem seen with the micro-LED display with color conversion layers is crosstalk contamination, where light from one micro-LED unintentionally leaks from one pixel to an adjacent pixel. Crosstalk can cause poor display image quality due to poor color mixture.

Traditionally, there are a number of ways to resolve crosstalk in these types of displays. First, the light output from the micro-LEDs can be collimated by an appropriate collimation layer (e.g., a structured layer which redirects light into a column). However, this is difficult to do for very small LED chip sizes. Second, a black matrix (like a light-absorbing wall) can be placed between each pixel to reduce light leakage. This solution, however, adds significant difficulty to the manufacturing process. Third, a display cell can be built with a very small gap between the micro-LED array and the color conversion layer, but this requires a very thin adhesive layer (less than 10 microns) between the micro-LED array and conversion layer which makes it tough to create a uniform thickness that also covers the entire micro-LED array.

According to some aspects of the present description, a display includes a multilayer optical film having an off-axis spectrum shift combined with a light emission film (LED or micro-LED array) and a light converting film (film with color-converting pixels, such as color-converting filters) so that light emitted by the LEDs at higher incident angles is substantially reflected back by the optical film. In some embodiments, for example, a display includes a light emission film, a light-converting film, and an optical film disposed between, and substantially co-extensive in length (e.g., along a y-axis of the display) and width (e.g., along an x-axis of the display) with, the light emission and light-converting films. In some embodiments, the optical film may be bonded to the light emission film and the light-converting film with respective first and second bonding layers. In some embodiments, the light emission film includes a plurality of first pixels arranged at an average spacing d1 from each other and configured to emit light having substantially a same emitted spectrum having an emission peak at an emitted peak wavelength (e.g., a blue wavelength, such as 446 nm).

In some embodiments, the light-converting film may include a plurality of second pixels arranged at an average spacing d2 from each other and disposed on, and aligned in one-to-one correspondence with, the first pixels. In some embodiments, the light emission and light-converting films may be spaced apart from each other by an average distance D along a thickness direction (e.g., along a z-axis) of the display. In some embodiments, the plurality of second pixels may include at least pluralities of light-converting green pixels and light-converting red pixels having respective green and red converting spectra and configured to receive and convert at least portions of the emitted light from their corresponding first pixels to respective green and red light within the respective green and red converting spectra. For example, the first pixels of the light emitting film may emit blue light which is subsequently converted to green and red light after being transmitted by the light-converting green and red pixels. In some embodiments, the first pixels emit blue light with the emission peak at a blue peak wavelength (e.g., about 446 nm) in a wavelength range from about 430 nm to about 450 nm. In some other embodiments, the first pixels may emit ultraviolet light with the emission peak at an ultraviolet peak wavelength of less than about 430 nm.

In some embodiments, the optical film may include a plurality of alternating microlayers numbering at least 10, or at least 25, or at least 50, or at least 100, or at least 150, or at least 200, or at least 250, or at least 300, or at least 350, or at least 400, or at least 450, or at least 500 in total. In some embodiments, each of the microlayers may have an average thickness of less than about 500 nm, or less than about 450 nm, or less than about 400 nm, or less than about 350 nm, or less than about 300 nm, or less than about 250 nm, or less than about 200 nm. In some embodiments, the optical film further includes at least one skin layer disposed on the microlayers and having an average thickness of greater than about 500 nm, or greater than about 750 nm, or greater than about 1000 nm, or greater than about 1500 nm, or greater than about 2000 nm.

In some embodiments, for the emitted peak wavelength and at least one polarization state (e.g., polarized to the x-axis or y-axis of the film, and may be mutually orthogonal polarization states), the optical film may have an optical transmittance T1 for a first incident angle a1 of less than about 10 degrees, or less than about 8 degrees, or less than about 6 degrees, or less than about 4 degrees, or less than about 2 degrees, or less than about 1 degrees (e.g., about 0 degrees) and an optical transmittance T2 for a different, second incident angle a2, such that tan(a2)=(d1+d2)/(2D), and the ratio T2/T1 is less than or equal to about 0.8, or about 0.75, or about 0.7, or about 0.65, or about 0.6, or about 0.5, or about 0.4, or about 0.3, or about 0.2, or about 0.1, or about 0.05. In some embodiments, the second incident angle a2 may be greater than about 20 degrees, or greater than about 25 degrees, or greater than about 30 degrees, or greater than about 40 degrees, or greater than about 45 degrees, or greater than about 50 degrees, or greater than about 55 degrees, or greater than about 60 degrees.

In some embodiments, the distance d1 is in a range from about 5 microns to about 50 microns, or from about 10 microns to about 45 microns, or from about 15 microns to about 40 microns, or from about 20 microns to about 35 microns, or from about 25 microns to about 30 microns. In some embodiments, the distance d2 is in a range from about 5 microns to about 50 microns, or from about 10 microns to about 45 microns, or from about 15 microns to about 40 microns, or from about 20 microns to from about 35 microns, or from about 25 microns to about 30 microns. In some embodiments, the distance D is in a range from about 20 microns to about 100 microns, or from about 25 microns to about 95 microns, or from about 30 microns to about 90 microns, or from about 35 microns to about 85 microns, or from about 40 microns to about 80 microns, or from about 45 microns to about 75 microns, or from about 50 microns to about 70 microns.

In some embodiments, the green converting spectrum may have a green peak at a green peak wavelength (e.g., about 532 nm) in a wavelength range from about 520 nm to about 550 nm. In some embodiments, the red converting spectrum may have a red peak at a red peak wavelength (e.g., about 630 nm) in a wavelength range from about 610 nm to about 650 nm.

In embodiments where the first pixels emit ultraviolet light with the emission peak at an ultraviolet peak wavelength of less than about 430 nm, the plurality of second pixels may further include a plurality of light-converting blue pixels having a blue converting spectrum configured to receive and convert at least portions of the ultraviolet emitted light from the corresponding first pixels to blue light within the blue converting spectrum. In some such embodiments, the blue converting spectrum may have a blue peak at a blue peak wavelength (e.g., about 446 nm) in a wavelength range from about 430 nm to about 450 nm.

In some embodiments, the first pixels of the light emission film may be arranged on a first substrate. In some embodiments, the second pixels of the light-converting film may be arranged on a second substrate.

According to some aspects of the present description, a display may include a light emission film, a light-converting film, and an optical film disposed between, and substantially co-extensive in length (e.g., a y-axis of the display) and width (e.g., an x-axis of the display) with, the light emission and light-converting films. In some embodiments, the optical film may be bonded to the light emission film and the light-converting film with respective first and second bonding layers.

In some embodiments, the light emission film may include a plurality of blue pixels configured to emit blue light having an emitted spectrum having an emission peak and a corresponding blue full width at half maximum FWHM. In some embodiments, the light-converting film may include pluralities of light-converting green pixels and light-converting red pixels having respective green and red converting spectra with respective green and red peaks and corresponding respective green full width at half maximum, FWHM(g), and red full width at half maximum, FWHM(r).

In some embodiments, for each of mutually orthogonal first (e.g., x-axis) and second (e.g., y-axis) polarization states, and for wavelength ranges across FWHM(b), FWHM(g) and FWHM(r), the optical film may have respective average optical transmittances S1b, S1g, and S1r for a first incident angle a1 of less than about 10, or less than about 8 degrees, or less than about 6 degrees, or less than about 4 degrees, or less than about 2 degrees, or less than about 1 degree and respective average optical transmittances S2b, S2g, and S2r for a different, second incident angle a2 of greater than about 20 degrees, or greater than about 25 degrees, or greater than about 30 degrees, or greater than about 40 degrees, or greater than about 45 degrees, or greater than about 50 degrees, or greater than about 55 degrees, or greater than about 60 degrees.

In some embodiments, each of S1g, S1r, S2g, and S2r may be less than about 15%, or less than about 12.5%, or less than about 10%, or less than about 7.5%, or less than about 5%, or less than about 2.5%, or less than about 1%. In some embodiments, S1b may be greater than about 60%, or greater than about 65%, or greater than about 70%, or greater than about 75%, or greater than about 80%, or greater than about 85%. In some embodiments, S2b may be less than about 60%, or less than about 55%, or less than about 50%, or less than about 45%, or less than about 40%, or less than about 35%, or less than about 30%, or less than about 25%, or less than about 20%, or less than about 15%, or less than about 10%, or less than about 5%, or less than about 1%.

In some embodiments, the blue pixels may be arranged at an average spacing d1 from each other, and the green and red pixels, in combination, are arranged at an average spacing d2 from each other, and the light emission and light-converting films are spaced apart from each other by an average distance D along a thickness direction (e.g., a z-axis) of the display, such that tan(a2)=(d1+d2)/(2D).

In some embodiments, the optical film may include a plurality of alternating microlayers numbering at least 10, or at least 25, or at least 50, or at least 100, or at least 150, or at least 200, or at least 250, or at least 300, or at least 350, or at least 400, or at least 450, or at least 500 in total. In some embodiments, each of the microlayers may have an average thickness of less than about 500 nm, or less than about 450 nm, or less than about 400 nm, or less than about 350 nm, or less than about 300 nm, or less than about 250 nm, or less than about 200 nm. In some embodiments, the optical film further includes at least one skin layer disposed on the microlayers and having an average thickness of greater than about 500 nm, or greater than about 750 nm, or greater than about 1000 nm, or greater than about 1500 nm, or greater than about 2000 nm.

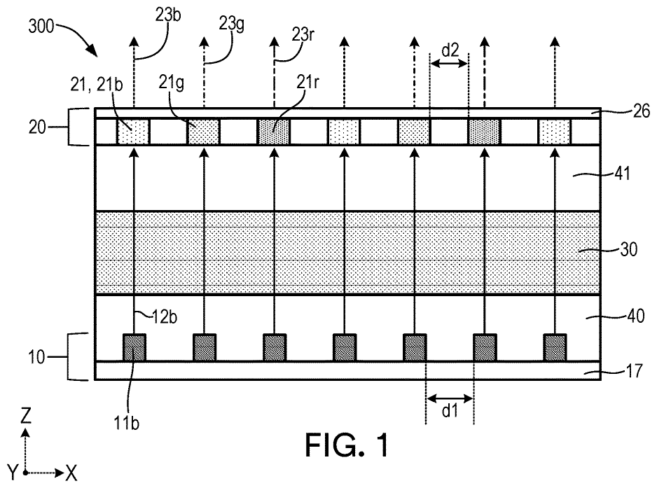

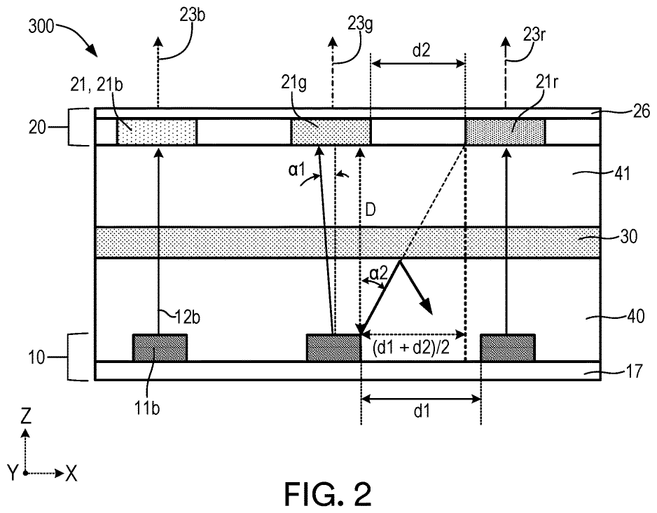

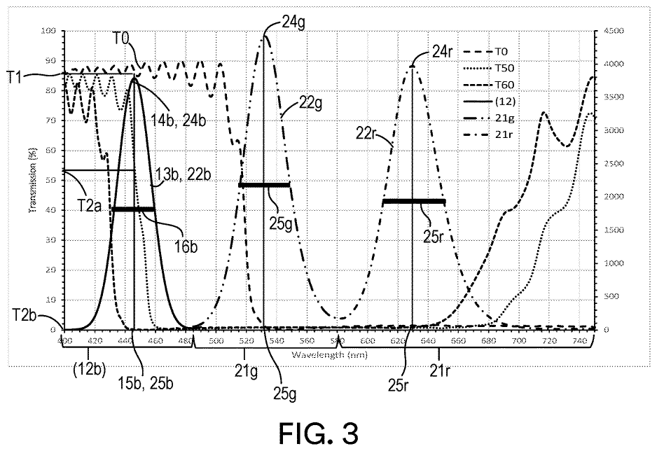

Turning now to the figures, FIGS. 1 and 2 provide side views of an embodiments of a display 300 with reduced crosstalk contamination, according to the present description. FIGS. 1 and 2 should be reviewed together for the following discussion. In some embodiments, display 300 includes a light emission film 10, a light-converting film 20, and an optical film 30 disposed between the light emission film 10 and the light-converting film 20. In some embodiments, light emission film 10 may include a plurality of first pixels 11b arranged at an average spacing d1 from each other and configured to emit light 12b having substantially a same emitted spectrum having an emission peak at an emitted peak wavelength (e.g., a blue light such as 446 nm or an ultraviolet light less than 430 nm). Additional information on optical wavelengths of some embodiments of the display 300 will be discussed with FIG. 3 elsewhere herein.

In some embodiments, the light-converting film 20 may include a plurality of second pixels 21/21b, 21g, 21r arranged at an average spacing d2 from each other. In some embodiments, the plurality of second pixels 21/21b, 21g, 21r may be disposed on, and aligned in one-to-one correspondence with, first pixels 11b.

In some embodiments, the light emission film 10 and light-converting film 20 may be spaced apart from each other by an average distance D (see FIG. 2) along a thickness direction of the display (e.g., along the z-axis shown in FIGS. 1 and 2). In some embodiments, the plurality of second pixels 21/21b, 21g, 21r may include at least pluralities of light-converting green pixels 21g and light-converting red pixels 21r having respective green converting spectra and red converting spectra, and which are configured to receive and convert at least portions of emitted light 12b from their corresponding first pixels to respective green light 23g and red light 23r light within the respective green and red converting spectra.

In some embodiments, when the first pixels 11b emit a blue wavelength of light 12b (e.g., a light with a wavelength between about 430 nm and about 450 nm), the plurality of second pixels 21/21b, 21g, 21r may include light-transmitting pixels 21 which substantially transmit light 12b without converting it (that is, as the light is already blue, it doesn't need to be converted). In other embodiments, when first pixels 11b emit ultraviolet light with the emission peak at an ultraviolet peak wavelength of less than about 430 nm, the plurality of second pixels 21/21b, 21g, 21r may include a plurality of light-converting blue pixels 21b having a blue converting spectrum configured to receive and convert at least portions of the ultraviolet emitted light 12b from the corresponding first pixels 11b to blue light 23b within the blue converting spectrum.

In some embodiments, optical film 30 may be bonded to light emission film 10 and light-converting film 20 with respective first 40 and second 41 bonding layers. In some embodiments, first pixels 11b of light emission film 10 may be arranged on a first substrate 17. In some embodiments, second pixels 21/21b, 21g, 21r of light-converting film 20 may be arranged on a second substrate 26.

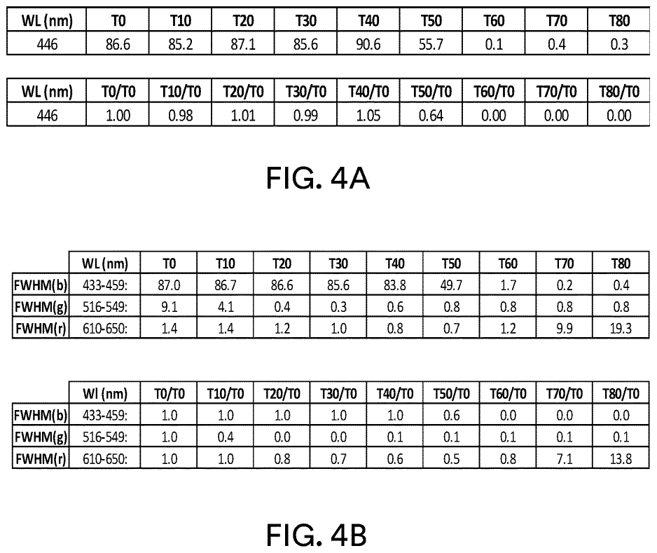

Looking specifically at FIG. 2 now, additional information on the arrangement or geometry of display 300 is shown. In some embodiments, optical film 30 is substantially co-extensive in length (e.g., the y-axis of FIG. 2) and width (e.g., the x-axis of FIG. 2) with, light emission film 10 and light-converting film 20. In some embodiments, optical film 30 may include a plurality of microlayers (see, e.g., FIG. 4) numbering at least 10 in total configured such that, for the emitted peak wavelength and at least one polarization state (e.g., light polarized along the x-axis or y-axis of the film shown in FIG. 2), the optical film may have an optical transmittance T1 for a first incident angle α1 of less than about 10 degrees and an optical transmittance T2 for a different, second incident angle α2 (e.g., an angle of 40 degrees, or 50 degrees, or 60 degrees), such that tan(α2)=(d1+d2)/(2D), and the ratio T2/T1 is less than or equal to about 0.8. Stated another way, optical film 30 may be configured to substantially transmit light at a low angle of incidence to a normal of the film (e.g., less than about 10 degrees), and to substantially reflect light at a higher angle of incidence (e.g., greater than about 20 degrees). In some embodiments, the amount of transmission may vary continuously over a range of angles of incidence. Additional details on the optical characteristics of display 300 are provided in FIG. 3.

FIG. 3 is a graph plotting the optical transmittances for an embodiment of a display with reduced crosstalk contamination, such as display 300 of FIGS. 1 and 2. FIGS. 4A and 4B are tables summarizing optical transmittance data for a display with reduced crosstalk contamination, as seen in the graph of FIG. 3. FIGS. 3, 4A, and 4B should be reviewed together for the following discussion.

Looking at the plots of FIG. 3, the graph shows six separate plot lines, including the following plotlines:
T0, optical transmittance of optical film 30 as seen in FIG. 1 (e.g., micro-LEDs) at an incidence angle of 0 degrees.
T50, optical transmittance of optical film 30 at an incidence angle of 50 degrees.
T60, optical transmittance of optical film 30 at an incidence angle of 60 degrees.
12b(12), the emission spectra of first pixels 11b as seen in FIG. 1.
21g, the emission spectra of light-converting green pixels 21g.
21r, the emission spectra of light-converting red pixels 21r.

In some embodiments, optical film 30 is configured such that for an emitted peak wavelength 15b (e.g., about 446 nm) and at least one polarization state, optical film 30 may have an optical transmittance T1 (e.g., about 86.6%, as shown for the embodiment of FIG. 3, and as summarized in FIG. 4A) for a first incident angle of less than about 10 degrees (e.g., 0 degrees, T0) and an optical transmittance T2 (e.g., as shown by T2a and T2b of FIG. 3) for a different second incident angle (respectively, about 55.7% at 50 deg and about 0.1% at 60 deg). In some embodiments, the ratio of T2 divided by T1 may be less than or equal to about 0.8 (e.g., 0.64 at 50 deg, 0.0 at 60 deg, see FIG. 4A).

In some embodiments, the green converting spectrum has a green peak 24g at a green peak wavelength (25g, at about 532 nm) in a wavelength range from about 520 nm to about 550 nm. In some embodiments, the red converting spectrum has a red peak 24r at a red peak wavelength (25r, at about 630 nm) in a wavelength range from about 610 nm to about 650 nm.

In some embodiments, the blue converting spectrum has a blue peak 24b at a blue peak wavelength (25b, at about 446 nm) in a wavelength range from about 430 nm to about 450 nm. In some embodiments, light emission film 10 (e.g., film 10, FIG. 1) includes a plurality of blue pixels configured to emit blue light 12b having an emitted spectrum 13b comprising an emission peak 14b and a corresponding blue full width at half maximum FWHM(b) 16b.

In some embodiments, light light-converting film 20 (e.g., film 20, FIG. 1) includes pluralities of light-converting green 21g and red 21r pixels having respective green converting spectra 22g and red converting spectra 22r and having a respective green peak 24g and red peak 24r, and corresponding respective green full width at half maximum FWHM(g) 25g and red full width at half maximum FWHM(r) 25r.

As seen by examining the plots of FIG. 3 and data of FIG. 4B, optical film 30 (e.g., film 30, FIG. 1), for each of mutually orthogonal first (e.g., x-axis) and second (e.g., y-axis) polarization states, and for wavelength ranges across FWHM(b), FWHM(g) and FWHM(r), the optical film may have respective average optical transmittances S1b (about 87%, average transmittance taken across the wavelength range represented by FWHM(b) as shown in FIG. 3), S1g (about 9.1%, average transmission across FWHM(g) in FIG. 3) and S1r (about 1.4%, average transmission across FWHM(r) in FIG. 3) for a first incident angle of less than about 10 degrees (e.g., about 0 degrees) and respective average optical transmittances S2b (about 49.7% at 50 deg; about 1.7% at 60 deg), S2g (about 0.8% at 50 deg; about 0.8% at 60 deg) and S2r (about 0.7% at 50 deg; about 1.2% at 60 deg) for a different, second incident angle the second incident angle of greater than about 20 degrees (e.g., about 50 degrees and about 60 degrees, as shown in FIG. 3), such that: each of S1g, S1r, S2g, and S2r is less than about 15%, or less than about 12.5%, or less than about 10%, or less than about 7.5%, or less than about 5%, or less than about 2.5%, or less than about 1%; S1b is greater than about 60%, or greater than about 65%, or greater than about 70%, or greater than about 75%, or greater than about 80%, or greater than about 85%; and S2b is less than about 60%, or less than about 55%, or less than about 50%, or less than about 45%, or less than about 40%, or less than about 35%, or less than about 30%, or less than about 25%, or less than about 20%, or less than about 15%, or less than about 10%, or less than about 5%, or less than about 1%.

In summary, the data shown for the embodiment of optical film 30 shown in FIGS. 3, 4A, and 4B shows that a significant reduction in off-angle (crosstalk) transmission can be achieved using an optical film which has been configured to have optical characteristics which substantially allow transmission of light at low angles of incidence (i.e., near on-axis transmissions) and substantially block or reduce transmission of light at higher angles of incidence (i.e., those angles associated with crosstalk contamination).

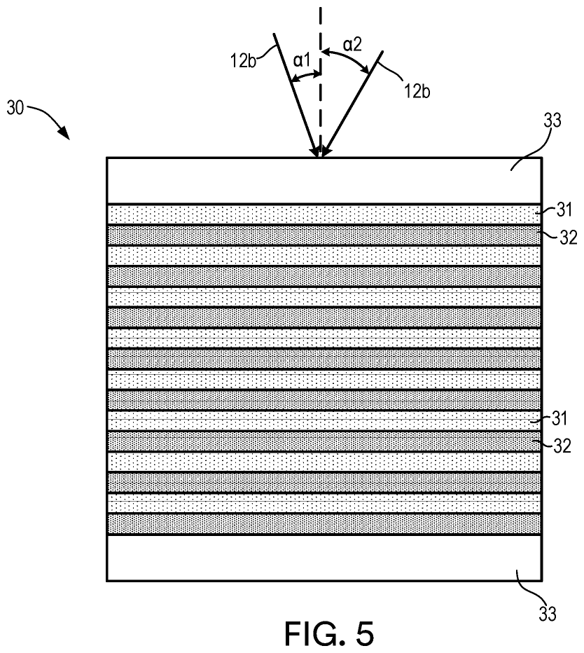

An optical film such as this may be created by alternating microlayers having different indices of refraction, such as the embodiment of a multilayer optical film 30 shown in FIG. 5. FIG. 5 is a cross-sectional, side view of an embodiment of a multilayer optical film 30 including a plurality of alternating microlayers 31 and 32. Microlayers 31, 32 may, in some embodiments, number at least 10, or at least 25, or at least 50, or at least 100, or at least 150, or at least 200, or at least 250, or at least 300, or at least 350, or at least 400, or at least 450, or at least 500 in total. In some embodiments, each of microlayers 31, 32 may an average thickness of less than about 500 nm, or less than about 450 nm, or less than about 400 nm, or less than about 350 nm, or less than about 300 nm, or less than about 250 nm, or less than about 200 nm.

The total number of microlayers 31, 32, as well as the thickness profile or gradient across the plurality of microlayers 31, 32, and the differences in indices of refraction between adjacent microlayers 31, 32 can be configured such that the resulting optical film 30 exhibits a desired set of optical characteristics (e.g., optical transmission versus wavelength such as that shown in FIG. 3). That is, an optical film 30 may be configured with exhibits a higher optical transmission for light 12b (see FIG. 1 and FIG. 5) that has an angle of incidence less than about 10 degrees (α1) and a lower optical transmission for light 12b at an angle of incidence greater than about 20 degrees (α2). In some embodiments, optical film 30 may further include at least one skin layer 33 disposed on microlayers 31, 32 having an average thickness of greater than about 500, or about 750 nm, or about 1000 nm, or about 1500 nm, or about 2000 nm.

Terms such as “about” will be understood in the context in which they are used and described in the present description by one of ordinary skill in the art. If the use of “about” as applied to quantities expressing feature sizes, amounts, and physical properties is not otherwise clear to one of ordinary skill in the art in the context in which it is used and described in the present description, “about” will be understood to mean within 10 percent of the specified value. A quantity given as about a specified value can be precisely the specified value. For example, if it is not otherwise clear to one of ordinary skill in the art in the context in which it is used and described in the present description, a quantity having a value of about 1, means that the quantity has a value between 0.9 and 1.1, and that the value could be 1.

Terms such as “substantially” will be understood in the context in which they are used and described in the present description by one of ordinary skill in the art. If the use of “substantially equal” is not otherwise clear to one of ordinary skill in the art in the context in which it is used and described in the present description, “substantially equal” will mean about equal where about is as described above. If the use of “substantially parallel” is not otherwise clear to one of ordinary skill in the art in the context in which it is used and described in the present description, “substantially parallel” will mean within 30 degrees of parallel. Directions or surfaces described as substantially parallel to one another may, in some embodiments, be within 20 degrees, or within 10 degrees of parallel, or may be parallel or nominally parallel. If the use of “substantially aligned” is not otherwise clear to one of ordinary skill in the art in the context in which it is used and described in the present description, “substantially aligned” will mean aligned to within 20% of a width of the objects being aligned. Objects described as substantially aligned may, in some embodiments, be aligned to within 10% or to within 5% of a width of the objects being aligned.

All references, patents, and patent applications referenced in the foregoing are hereby incorporated herein by reference in their entirety in a consistent manner. In the event of inconsistencies or contradictions between portions of the incorporated references and this application, the information in the preceding description shall control.

Descriptions for elements in figures should be understood to apply equally to corresponding elements in other figures, unless indicated otherwise. Although specific embodiments have been illustrated and described herein, it will be appreciated by those of ordinary skill in the art that a variety of alternate and/or equivalent implementations can be substituted for the specific embodiments shown and described without departing from the scope of the present disclosure. This application is intended to cover any adaptations or variations of the specific embodiments discussed herein. Therefore, it is intended that this disclosure be limited only by the claims and the equivalents thereof.

What is claimed:

1. A display comprising:
a light emission film comprising a plurality of first pixels arranged at an average spacing d1 from each other and configured to emit light having substantially a same emitted spectrum comprising an emission peak at an emitted peak wavelength;
a light-converting film comprising a plurality of second pixels arranged at an average spacing d2 from each other and disposed on, and aligned in one-to-one correspondence with, the first pixels, the light emission and light-converting films spaced apart from each other by an average distance D along a thickness direction of the display, the plurality of second pixels comprising at least pluralities of light-converting green and red pixels comprising respective green and red converting spectra and configured to receive and convert at least portions of the emitted light from their corresponding first pixels to respective green and red light within the respective green and red converting spectra; and
an optical film disposed between, and substantially co-extensive in length and width with, the light emission and light-converting films and comprising a plurality of microlayers numbering at least 10 in total, each of the microlayers having an average thickness of less than about 500 nm, such that for the emitted peak wavelength and at least one polarization state, the optical film has an optical transmittance T1 for a first incident angle a1 of less than about 10 degrees and an optical transmittance T2 for a different second incident angle a2, tan(a2)=(d1+d2)/(2D), T2/T1≤0.8.

2. The display of claim 1, wherein the second incident angle a2 is greater than about 20 degrees.

3. The display system of claim 1, wherein the first pixels emit blue light with the emission peak at a blue peak wavelength in a wavelength range from about 430 nm to about 450 nm.

4. The display system of claim 1, wherein the d1 is in a range from about 5 microns to about 50 microns.

5. The display system of claim 1, wherein the d2 is in a range from about 5 microns to about 50 microns.

6. The display system of claim 1, wherein the D is in a range from about 20 microns to about 100 microns.

7. The display system of claim 1, wherein the green converting spectrum has a green peak at a green peak wavelength in a wavelength range from about 520 nm to about 550 nm.

8. The display system of claim 1, wherein the red converting spectrum has a red peak at a red peak wavelength in a wavelength range from about 610 nm to about 650 nm.

9. The display system of claim 1, wherein the optical film further comprises at least one skin layer disposed on the microlayers and having an average thickness of greater than about 500 nm.

10. The display system of claim 1, wherein the first pixels emit ultraviolet light with the emission peak at an ultraviolet peak wavelength of less than about 430 nm.

11. The display system of claim 10, wherein the plurality of second pixels further comprises a plurality of light-converting blue pixels comprising a blue converting spectrum configured to receive and convert at least portions of the ultraviolet emitted light from the corresponding first pixels to blue light within the blue converting spectrum.

12. The display system of claim 11, wherein the blue converting spectrum has a blue peak at a blue peak wavelength in a wavelength range from about 430 nm to about 450 nm.

13. The display system of claim 1, wherein the at least one polarization state comprises each of mutually orthogonal first and second polarization states.

14. The display system of claim 1, wherein the optical film is bonded to the light emission film and the light-converting film with respective first and second bonding layers.

15. The display system of claim 1, wherein the first pixels of the light emission film are arranged on a first substrate.

16. The display system of claim 1, wherein the second pixels of the light-converting film are arranged on a second substrate.

17. A display comprising:
a light emission film comprising a plurality of blue pixels configured to emit blue light having an emitted spectrum comprising an emission peak and a corresponding blue full width at half maximum FWHM(b);
a light-converting film comprising pluralities of light-converting green and red pixels comprising respective green and red converting spectra comprising respective green and red peaks and corresponding respective a green full width at half maximum FWHM(g) and a red full width at half maximum FWHM(r); and
an optical film disposed between, and substantially co-extensive in length and width with, the light emission and light-converting films, such that for each of mutually orthogonal first and second polarization states, and for wavelength ranges across FWHM(b), FWHM(g) and FWHM(r), the optical film has respective average optical transmittances S1b, S1g, and S1r for a first incident angle of less than about 10 degrees and respective average optical transmittances S2b, S2g, and S2r for a different second incident angle the second incident angle of greater than about 20 degrees, wherein:
each of S1g, S1r, S2g and S2r is less than about 15%;
S1b is greater than about 60%; and
S2b is less than about 60%.

18. The display system of claim 17, wherein the blue pixels are arranged at an average spacing d1 from each other, wherein the green and red pixels, in combination, are arranged at an average spacing d2 from each other, wherein the light emission and light-converting films are spaced apart from each other by an average distance D along a thickness direction of the display, wherein for the second incident angle is a2, wherein tan(a2)=(d1+d2)/(2D).

19. The display system of claim 17, wherein the optical film comprises a plurality of microlayers numbering at least 10 in total, each of the microlayers having an average thickness of less than about 500 nm.

20. The display system of claim 17, wherein the optical film is bonded to the light emission film and the light-converting film with respective first and second bonding layers.
